(19) United States
(12) Patent Application Publication
(10) Pub. No.: US 2012/0160808 A1
(43) Pub. Date: Jun. 28, 2012

(54) SUBSTRATE PROCESSING APPARATUS AND SUBSTRATE PROCESSING METHOD

(75) Inventors: Eiichiro KIKUCHI, Kurokawa-gun (JP); Nobuyuki NAGAYAMA, Kurokawa-gun (JP); Takahiro MIYAI, Fuchu City (JP)

(73) Assignee: TOKYO ELECTRON LIMITED, Tokyo (JP)

(21) Appl. No.: 13/332,986

(22) Filed: Dec. 21, 2011

Related U.S. Application Data
(60) Provisional application No. 61/432,799, filed on Jan. 14, 2011.

(30) Foreign Application Priority Data
Dec. 22, 2010 (JP) 2010-286075

(51) Int. Cl. H01L 21/3065

(52) U.S. Cl. 216/67; 156/345.52

(57) ABSTRACT

A substrate processing apparatus includes: a holding stage which includes a susceptor having a substrate holding surface on which a wafer is held and a focus ring holding surface on which a focus ring is held; an electrostatic chuck which electrostatically adsorbs a rear surface of the wafer to the substrate holding surface and electrostatically adsorbs a rear surface of the focus ring to the focus ring holding surface; and a heat transfer gas supplying mechanism, wherein the heat transfer gas supplying mechanism independently provides a first heat transfer gas supply unit supplying a first heat transfer gas to the rear surface of the substrate and a second heat transfer gas supply unit supplying a second heat transfer gas to the rear surface of the focus ring.

### CROSS-REFERENCE TO RELATED PATENT APPLICATIONS

This application claims the benefit of Japanese Patent Application No. 2010-286075, filed on Dec. 22, 2010, in the Japan Patent Office, and U.S. Patent Application No. 61/432,799, filed on Jan. 14, 2011, in the United States Patent and Trademark Office, the disclosures of which are incorporated herein in their entireties by reference.

### BACKGROUND OF THE INVENTION

1. Field of the Invention

The present invention relates to a substrate processing apparatus and a substrate processing method, which perform a plasma process on a substrate, such as a semiconductor wafer.

2. Description of the Related Art

During a manufacturing process of a semiconductor device, a plasma process, such as etching or film-forming, is repeatedly performed so as to form a minute circuit pattern on a substrate, such as a semiconductor wafer. In the plasma process, for example, plasma is generated by applying a radio frequency voltage between electrodes facing each other in a processing chamber of a substrate processing apparatus configured to be depressurizable, and the plasma affects the substrate held on a holding stage to perform etching.

During such a plasma process, the etching is performed by disposing a focus ring on the holding stage such that the focus ring surrounds the substrate on the holding stage, so that a uniform and satisfactory process is performed in an edge portion like in a center portion of the substrate. Here, in order to prevent a temperature increase of the substrate due to a heat input received from the plasma, a substrate holding unit for electrostatically holding the substrate is provided on the holding stage while supplying a heat transfer gas, such as a He gas, to a rear surface of the substrate to increase thermal conductivity with a susceptor, thereby uniformly maintaining the temperature of the substrate.

However, since not only the substrate but also the focus ring around the substrate is exposed to the plasma during the plasma process, the temperature of the focus ring may also fluctuate due to the heat input of the plasma. Thus, in-plane process characteristics (process characteristics such as an etching rate) of the surface may be affected.

In order to prevent process characteristics of a vicinity portion of the substrate from fluctuating due to heat stored in a characteristic compensating ring provided around the substrate, as the plasma process is repeated, the characteristic compensating ring is also electrostatically held while the heat transfer gas supplied to the rear surface of the substrate is branched and also supplied to a rear surface of the characteristic compensating ring (for example, refer to Patent Document 1).

However, the in-plane process characteristics of the substrate cannot be controlled under certain process conditions (a gas species, a gas flow rate, a pressure in the processing chamber, and an amount of radio frequency power) of the substrate, just by supplying the heat transfer gas to the rear surface of the substrate and the rear surface of the characteristic compensating ring by using one line as disclosed in Patent Document 1. Since the same species of heat transfer gas is supplied to both the rear surface of the substrate and the rear surface of the characteristic compensating ring under the same pressure in Patent Document 1, the in-plane process characteristics of the substrate cannot be freely controlled by the heat transfer gas.

[Patent Document 1] Japanese Laid-Open Patent Publication No. hei 10-303288

### SUMMARY OF THE INVENTION

The present invention provides a substrate processing apparatus etc., where the temperature of a focus ring is independently controlled from the temperature of a substrate, thereby freely controlling in-plane process characteristics of the substrate.

According to an aspect of the present invention, there is provided a substrate processing apparatus which performs a plasma process on a substrate, with the substrate being disposed in a processing chamber and a focus ring being disposed to surround the substrate, the substrate processing apparatus including: a holding stage which includes a susceptor having a substrate holding surface on which the substrate is held and a focus ring holding surface on which the focus ring is held; a susceptor temperature control mechanism which adjusts a temperature of the susceptor; a substrate holding unit which electrostatically adsorbs a rear surface of the substrate to the substrate holding surface and electrostatically adsorbs a rear surface of the focus ring to the focus ring holding surface; and a heat transfer gas supplying mechanism to which a first heat transfer gas supply unit supplying a first heat transfer gas to the rear surface of the substrate and a second heat transfer gas supply unit supplying a second heat transfer gas to the rear surface of the focus ring are independently provided.

Accordingly, the substrate is electrostatically adsorbed to the substrate holding surface of the substrate holding unit while the focus ring is electrostatically adsorbed to the focus ring holding surface. Furthermore, by independently providing the first heat transfer gas supply unit supplying the first heat transfer gas to the rear surface of the substrate and the second heat transfer gas supply unit supplying the second heat transfer gas to the rear surface of the focus ring, the second heat transfer gas may be supplied to the rear surface of the focus ring independently from the first heat transfer gas supplied to the rear surface of the substrate. Thus, thermal conductivity of the temperature controlled susceptor may be independently changed to independently control the temperature of the focus ring and the temperature of the substrate, thereby improving or freely controlling in-plane process characteristics of the substrate.

Also, the heat transfer gas supplying mechanism may independently provide a first gas passage connected to the first heat transfer gas supply unit and a second gas passage connected to the second heat transfer gas supply unit, wherein the first gas passage may communicate with a plurality of gas holes formed in the substrate holding surface and the second gas passage may communicate with a plurality of gas holes formed in the focus ring holding surface. Accordingly, thermal conductivity between the substrate and the susceptor and thermal conductivity between the focus ring and the susceptor may be independently controlled respectively by the first heat transfer gas from the gas holes of the substrate holding surface and the second heat transfer gas from the gas holes of the focus ring holding surface.

In this case, a first annular diffusion unit which is formed of an annular space along a circumferential direction of the focus ring may be provided below the focus ring holding surface, wherein the plurality of gas holes of the focus ring holding surface may communicate with the top of the first annular diffusion unit and the second gas passage may communicate with the bottom of the first annular diffusion unit. Accordingly, since the second heat transfer gas may be ejected from each gas hole while being diffused throughout the circumferential direction of the first annular diffusion unit by supplying the second transfer gas to the first annular diffusion unit through the second gas passage, the second transfer gas may be uniformly communicated throughout the rear surface of the focus ring.

Alternatively, the heat transfer gas supplying mechanism may independently provide a first gas passage connected to the first heat transfer gas supply unit and a second gas passage connected to the second heat transfer gas supply unit, wherein the first gas passage may communicate with a plurality of gas holes formed on the substrate holding surface, and the second gas passage may communicate with a second annular diffusion unit formed of an annular recess portion formed along a circumferential direction of the focus ring on the focus ring holding surface. Accordingly, the second heat transfer gas may be uniformly communicated throughout the rear surface of the focus ring since the second heat transfer gas may be diffused along the circumferential direction of the entire second annular diffusion unit immediately below the rear surface of the focus ring.

In this case, a plurality of protruding portions supporting the rear surface of the focus ring may be formed in the second annular diffusion unit. Accordingly, heat may be transferred by directly contacting the plurality of protruding portions to the rear surface of the focus ring. Thus, a portion heated by directly contacting the rear surface of the focus ring may be increased.

Also, a groove portion may be formed along a circumferential direction of the second annular diffusion unit below the second annular diffusion unit, wherein the second gas passage may communicate with the groove portion. Accordingly, even if it is difficult for the second heat transfer gas to be diffused due to a large number of protruding portions of the second annular diffusion unit, the second heat transfer gas may be easily and widely spread throughout the second annular diffusion unit since the second heat transfer gas from the second gas passage diffuses in the circumferential direction through the groove portion.

Alternatively, the heat transfer gas supplying mechanism may independently provide a first gas passage connected to the first heat transfer gas supply unit and a second gas passage connected to the second heat transfer gas supply unit, wherein the first gas passage may communicate with a plurality of gas holes formed on the substrate holding surface, and the second gas passage may communicate with a portion formed along a circumferential direction of the focus ring, wherein surface roughness of the portion may be rough enough for the second heat transfer gas to communicate to the focus ring holding surface. Accordingly, the second heat transfer gas from the second gas passage may be diffused throughout the circumferential direction of the focus ring through the rough surface of the focus ring holding surface.

In this case, a sealing portion which seals the second heat transfer gas may be provided on both inner and outer circumferences of the focus ring holding surface. Accordingly, it is difficult for the second heat transfer gas to leak from the focus ring holding surface, and thus a heat transfer effect according to the second heat transfer gas of the focus ring may be increased, thereby controlling process characteristics of an edge portion of the substrate.

Alternatively, the sealing portion on one or both inner and outer circumferences of the focus ring holding surface may be removed. Accordingly, not only the heat transfer effect according to the second heat transfer gas is increased, but also the second heat transfer gas may be leaked near the edge portion of the substrate, and thus the process characteristics of the edge portion of the substrate may be controlled even by changing a ratio of gas components near the edge portion.

Also, a sprayed film may be formed on a surface of the focus ring holding surface and a surface of the substrate holding surface, and in-plane process characteristics of the substrate may be controlled by changing porosity of the sprayed film of the focus ring holding surface with respect to porosity of the sprayed film of the substrate holding surface. In this case, the porosity of the sprayed film of the focus ring holding surface may be determined according to a control temperature range of the susceptor.

Alternatively, a plurality of gas holes in the substrate holding surface may be disposed in a center portion region of the substrate holding surface and an edge portion region of the substrate holding surface, with the edge portion region being around the center portion region, wherein the first gas passage may communicate with the plurality of gas holes in the center portion region of the substrate holding surface, and the second gas passage may be branched into two passages, wherein one passage may communicate with the plurality of gas holes formed in the focus ring holding surface and the other passage may communicate with the plurality of gas holes in the edge portion region of the substrate holding surface. Accordingly, the process characteristics of the edge portion region of the substrate may be directly controlled since the temperatures of not only the focus ring but also the edge portion region of the substrate may be independently controlled from the center portion region by the second heat transfer gas.

According to another aspect of the present invention, there is provided a substrate processing method of processing a substrate processing apparatus which performs a plasma process on a substrate, with the substrate being disposed in a processing chamber and a focus ring being disposed to surround the substrate, the substrate processing apparatus including: a holding stage which includes a susceptor having a substrate holding surface on which the substrate is held and a focus ring holding surface on which the focus ring is held; a susceptor temperature control mechanism which adjusts a temperature of the susceptor; a substrate holding unit which electrostatically adsorbs a rear surface of the substrate to the substrate holding surface and electrostatically adsorbs a rear surface of the focus ring to the focus ring holding surface; and a heat transfer gas supplying mechanism which independently provides a first heat transfer gas supply unit supplying a first heat transfer gas to a rear surface of the substrate under a predetermined pressure and a second heat transfer gas supply unit supplying a second heat transfer gas to a rear surface of the focus ring under a predetermined pressure, the substrate processing method including controlling in-plane process characteristics of the substrate are controlled by changing a supply pressure of the second heat transfer gas with respect to a supply pressure of the first heat transfer gas.

According to another aspect of the present invention, there is provided a substrate processing method of processing a substrate processing apparatus which performs a plasma process on a substrate, with the substrate being disposed in a processing chamber and a focus ring being disposed to surround the substrate, the substrate processing apparatus including: a holding stage which includes a susceptor having a substrate holding surface on which the substrate is held and a focus ring holding surface on which the focus ring is held; a susceptor temperature control mechanism which adjusts a temperature of the susceptor; a substrate holding unit which electrostatically adsorbs a rear surface of the substrate to the substrate holding surface and electrostatically adsorbs a rear surface of the focus ring to the focus ring holding surface; and a heat transfer gas supplying mechanism which independently provides a first heat transfer gas supply unit supplying a first heat transfer gas to a rear surface of the substrate under a predetermined pressure and a second heat transfer gas supply unit supplying a second heat transfer gas to a rear surface of the focus ring under a predetermined pressure, the substrate processing method including controlling in-plane process characteristics of the substrate are controlled by changing gas species of the first and second heat transfer gases.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view showing a configuration example of a substrate processing apparatus according to an embodiment of the present invention;

FIG. 2 is a cross-sectional view showing a configuration example of a heat transfer gas supplying mechanism according to the same embodiment;

FIG. 3A is a partial magnified cross-sectional view showing a configuration near a focus ring of FIG. 2;

FIG. 3B is a perspective view of a portion shown in FIG. 3A;

FIG. 4 is a graph showing a relationship between a pressure of a heat transfer gas and an etching rate in a wafer surface, according to the same embodiment, the graph showing an experimental result;

FIG. 5 is a diagram showing a specific example of a process sequence according to the same embodiment;

FIG. 6 is a diagram showing another specific example of a process sequence according to the same embodiment;

FIG. 7A is a partial cross-sectional view showing a modified example of communication structure of a second heat transfer gas in a focus ring holding surface;

FIG. 7B is a perspective view showing a portion excluding a focus ring shown in FIG. 7A;

FIG. 8A is a partial cross-sectional view showing another modified example of communication structure of a second heat transfer gas in a focus ring holding surface;

FIG. 8B is a partial cross-sectional view showing a case when a groove portion is provided in the modified example of FIG. 8A;

FIG. 9A is a partial cross-sectional view showing another modified example of communication structure of a second heat transfer gas in a focus ring holding surface, wherein sealing portions are provided at both inner and outer circumferences of a focus ring;

FIG. 9B is a partial cross-sectional view showing a case when the sealing portion is provided only at the inner circumference of the focus ring in the modified example of FIG. 9A;

FIG. 9C is a partial cross-sectional view showing a case when the sealing portion is provided only at the outer circumference of the focus ring in the modified example of FIG. 9A;

FIG. 9D is a partial cross-sectional view showing a case when the sealing portion is not provided at either of the inner and outer circumferences of the focus ring in the modified example of FIG. 9A;

FIG. 10A is a partial cross-sectional view conceptually showing a case when porosity of a focus ring holding surface is larger than porosity of a substrate holding surface, in a sprayed film forming a surface of an electrostatic chuck;

FIG. 10B is a partial cross-sectional view conceptually showing a case when porosity of a focus ring holding surface is smaller than porosity of a substrate holding surface, in a sprayed film forming a surface of an electrostatic chuck;

FIG. 10C is a partial cross-sectional view conceptually showing a case when there are two layers of sprayed film of a focus ring holding surface, in a sprayed film forming a surface of an electrostatic chuck; and

FIG. 11 is a cross-sectional view showing another configuration example of a heat transfer gas supplying mechanism according to the same embodiment.

### DETAILED DESCRIPTION OF THE INVENTION

Hereinafter, the present invention will be described in detail by explaining exemplary embodiments of the invention with reference to the attached drawings. Like reference numerals in the drawings denote like elements, and thus, descriptions thereof will be omitted.

(Substrate Processing Apparatus)

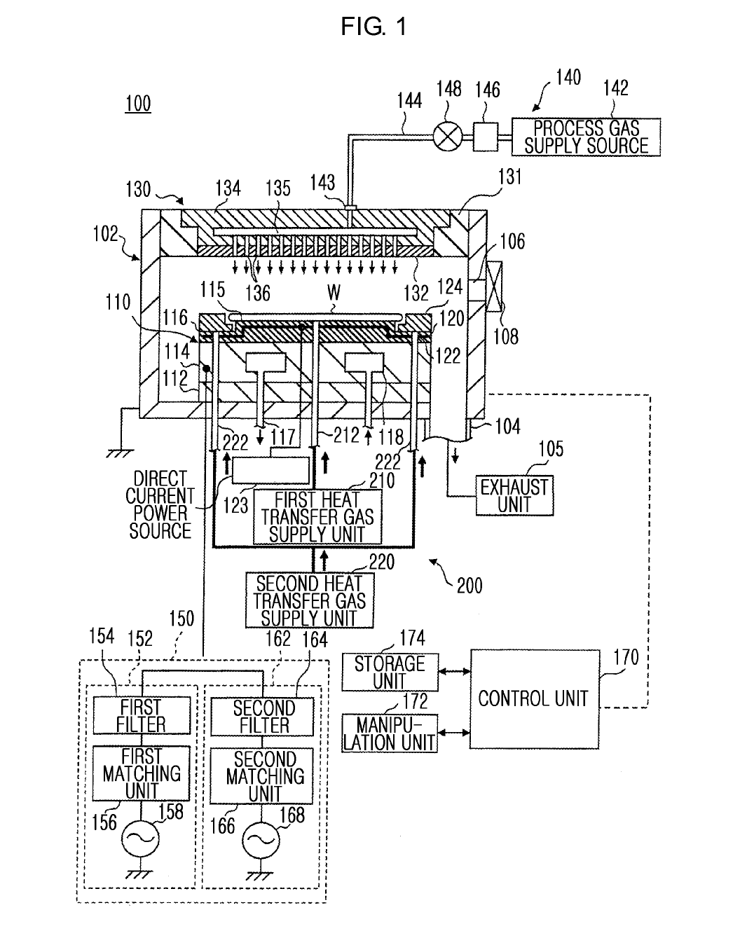

First, a schematic configuration of a substrate processing apparatus, according to an embodiment of the present invention, will be described with reference to the drawings. Here, the substrate processing apparatus is configured as a parallel plate type plasma processing apparatus. FIG. 1 is a longitudinal-sectional view showing a schematic configuration of a substrate processing apparatus 100, according to the present embodiment.

The substrate processing apparatus 100 includes, for example, a processing chamber 102 having a cylindrical processing container formed of aluminum of which a surface is anodized (alumite processed). The processing chamber 102 is grounded. A holding stage 110 having a substantially cylindrical shape for holding a wafer W thereon is provided at a lower portion inside the processing chamber 102. The holding stage 110 includes an insulator 112 having a plate shape and formed of ceramic, or the like, and a susceptor 114 constituting a lower electrode provided on the insulator 112.

The holding stage 110 includes a susceptor temperature adjusting unit 117 for adjusting the susceptor 114 to a predetermined temperature. The susceptor temperature adjusting unit 117 is configured to, for example, circulate a temperature adjusting medium in an annular temperature adjusting medium chamber 118 provided along a circumferential direction inside the susceptor 114.

An electrostatic chuck 120 is provided at an upper portion of the susceptor 114, as a substrate holding unit capable of adsorbing both of the wafer W and a focus ring 124 disposed to surround the wafer W. A substrate holding portion having a convex shape is formed at an upper middle portion of the electrostatic chuck 120, wherein a top surface of the substrate holding portion constitutes a substrate holding surface 115 on which the wafer W is held, and a lower top surface around the top surface constitutes a focus ring holding surface 116 on which the focus ring 124 is held.

The electrostatic chuck 120 is configured such that an electrode 122 is interposed between insulating materials. In the electrostatic chuck 120 according to the present embodiment, the electrode 122 extends not only to a lower side of the substrate holding surface 115 but also to a lower side of the focus ring holding surface 116, so as to adsorb both of the wafer W and the focus ring 124.

A predetermined direct current voltage (for example, 1.5 kV) is applied to the electrostatic chuck 120 from a direct current power source 123 connected to the electrode 112. Accordingly, the wafer W and the focus ring 124 are electrostatically adsorbed to the electrostatic chuck 120. Also, as shown in FIG. 1 as an example, the substrate holding portion may have a smaller diameter than a diameter of the wafer W, and an edge portion of the wafer W when the wafer W is held on the substrate holding portion protrudes from the substrate holding portion.

A heat transfer gas supplying mechanism 200 for supplying a heat transfer gas separately to a rear surface of the wafer W and a rear surface of the focus ring 124 is provided at the holding stage 110 according to the present embodiment. The heat transfer gas may be an Ar gas or an H₂ gas, besides a He gas that efficiently transfers heat through and cools down the wafer W or the focus ring 124 receiving plasma heat input by transferring a cool temperature of the susceptor 114 through the electrostatic chuck 120.

The heat transfer gas supplying mechanism 200 includes a first heat transfer gas supply unit 210 which supplies a first heat transfer gas to the rear surface of the wafer W held on the substrate holding surface 115, and a second heat transfer gas supply unit 220 which supplies a second heat transfer gas to the rear surface of the focus ring 124 held on the focus ring holding surface 116.

Thermal conductivity between the susceptor 114 and the wafer W, and thermal conductivity between the susceptor 114 and the focus ring 124 are individually controlled by using these heat transfer gases. For example, pressures or gas species of the first and second heat transfer gases may be changed. Accordingly, despite the heat input from plasma, in-plane uniformity of the wafer W may be improved while in-plane process characteristics of the wafer W may be controlled by aggressively differing a temperature of the wafer W and a temperature of the focus ring 124. Detailed configuration of the first heat transfer gas supply unit 210 and second heat transfer gas supply unit 220 will be described later.

An upper electrode 130 is provided above the susceptor 114 to face the susceptor 114. A plasma generating space is formed between the upper electrode 130 and the susceptor 114. The upper electrode 130 is supported by a top portion of the processing chamber 102 by interposing an insulating cover member 131 therebetween.

The upper electrode 130 mainly includes an electrode plate 132 and an electrode support 134 supporting the electrode plate 132 such that the electrode plate 132 is freely removable. The electrode plate 132 is formed of, for example, a silicon material, and the electrode support 134 is formed of, for example, a conductive material, such as aluminum a surface of which is alumite processed.

A process gas supply unit 140 for introducing a process gas from a process gas supply source 142 into the processing chamber 102 is provided at the electrode support 134. The process gas supply source 142 is connected to a gas inlet 143 of the electrode support 134 through a gas supply pipe 144.

As shown in FIG. 1 as an example, a mass flow controller (MFC) 146 and a opening/shutting valve 148 are sequentially provided from an upper stream of the gas supply pipe 144. A flow control system (FCS) may be provided instead of the MFC 146. A fluorocarbon gas (CₓF_{y}), such as a C₄F₈ gas, is supplied as a process gas for etching from the process gas supply source 142.

The process gas supply source 142 is configured to supply, for example, an etching gas for plasma etching. Also, only one process gas supply system including the gas supply pipe 144, the opening/shutting valve 148, the MFC 146, and the process gas supply source 142, etc. is shown in FIG. 1, but the substrate processing apparatus 100 includes a plurality of process gas supply systems. For example, flow rates of etching gases, such as a CF₄ gas, a O₂ gas, a N₂ gas, and a CHF₃ gas, are individually controlled to be supplied into the processing chamber 102.

A gas diffusion chamber 135, for example, having a substantially cylindrical shape is provided at the electrode support 134, and may uniformly diffuse the process gas introduced from the gas supply pipe 144. A plurality of gas discharge holes 136 discharging the process gas from the gas diffusion chamber 135 into the processing chamber 102 are formed at the lower portion of the electrode support 134 and the electrode plate 132. The process gas diffused in the gas diffusion chamber 135 is uniformly discharged toward the plasma generating space from the plurality of gas discharge holes 136. In this regard, the upper electrode 130 serves as a shower head for supplying the process gas.

Also, although not shown, a lifter for detaching the wafer W from the substrate holding surface 115 of the electrostatic chuck 120 by lifting the wafer W by using a lifter pin is provided at the holding stage 110.

An exhaust pipe 104 is connected to a lower portion of the processing chamber 102, and an exhaust unit 105 is connected to the exhaust pipe 104. The exhaust unit 105 includes a vacuum pump, such as a turbo molecular pump, and adjusts the inside of the processing chamber 102 to a predetermined depressurized atmosphere. Also, an inlet/outlet 106 for the wafer W is provided in a side wall of the processing chamber 102, and a gate valve 108 is provided at the inlet/outlet 106. The gate valve 108 is opened when the wafer W is transferred in and out. Also, the wafer W is transferred in and out through the inlet/outlet 106 by using a transfer arm (not shown), or the like.

A power supply device 150 supplying two-frequency duplex power is connected to the susceptor 114 constituting the lower electrode. The power supply device 150 includes a first radio frequency power supply mechanism 152 supplying first radio frequency power (plasma generating radio frequency power) of a first frequency, and a second radio frequency power supply mechanism 162 supplying a second radio frequency power (bias voltage generating radio frequency power) of a second frequency that is lower than the first frequency.

The first radio frequency power supply mechanism 152 includes a first filter 154, a first matching unit 156, and a first power source 158 sequentially connected from the susceptor 114. The first filter 154 prevents a power component of the second frequency from invading the first matching unit 156. The first matching unit 156 matches a first radio frequency power component.

The second radio frequency power supply mechanism 162 includes a second filter 164, a second matching unit 166, and a second power source 168 sequentially connected from the susceptor 114. The second filter 164 prevents a power component of the first frequency from invading the second matching unit 166. The second matching unit 166 matches a second radio frequency power component.

A control unit (general control device) 170 is connected to the substrate processing apparatus 100, and each element of the substrate processing apparatus 100 is controlled by the control unit 170. Also, a manipulation unit 172 including a keyboard with which an operator performs input manipulation of a command, or the like to manage the substrate processing apparatus 100, a display which visualizes and displays an operating status of the substrate processing apparatus 100, or a touch panel having both an input manipulation terminal function and a status display function, is connected to the control unit 170.

Also, a storage unit 174 storing a program for realizing various processes (a plasma process on the wafer W, etc.) executed by the substrate processing apparatus 100 via control of the control unit 170, or a process condition (recipe) or the like required to execute the program is connected to the control unit 170.

The storage unit 174 stores, for example, a plurality of process conditions (recipes). Each process condition is about a plurality of parameter values, such as a control parameter, a setting parameter, etc. to control each element of the substrate processing apparatus 100. Each process condition is about parameter values, such as a flow rate ratio of process gases, a pressure in a processing chamber, or a radio frequency power.

Also, the program or process condition may be stored in a hard disk or semiconductor memory, or set in a predetermined location of the storage unit 174 in a state accommodated in a transportable computer-readable recording medium, such as a CD-ROM or DVD.

The control unit 170 executes a desired process in the substrate processing apparatus 100 by controlling each element by reading a desired program or process condition from the storage unit 174 based on an instruction from the manipulation unit 172, and the like. Also, the control unit 170 may edit the process condition based on manipulation of the manipulation unit 172.

When the plasma process is performed on the wafer W held on the susceptor 114 in the substrate processing apparatus 100 having such a configuration, the first radio frequency of 10 MHz or above (for example, 100 MHz) is supplied from the first power source 158 to the susceptor 114 at a predetermined power while the second radio frequency of 2 MHz or above to less than 10 MHz (for example, 3 MHz) is supplied from the second power source 168 to the susceptor 114 at a predetermined power. Accordingly, plasma of the process gas is generated between the susceptor 114 and the upper electrode 130 due to the first radio frequency while a self bias voltage (−Vdc) is generated in the susceptor 114 due to the second radio frequency, and thus the plasma process may be performed on the wafer W. As such, by supplying and overlapping the first and second radio frequencies to the susceptor 114, the plasma may be suitably controlled to perform a satisfactory plasma process on the wafer W.

However, when the plasma is generated on the wafer W, not only the wafer W, but also the focus ring 124 around the wafer W, is exposed to the plasma, and thus receives heat input from the plasma. In this case, the susceptor 114 is controlled to a predetermined temperature, but the temperature of the focus ring 124 may fluctuate when thermal conductivity between the susceptor 114 and the focus ring 124 has a certain value. Specifically, if the temperature of the focus ring 124 fluctuates, the in-plane process characteristics of the wafer W may be affected.

Thus, according to the present embodiment, the heat transfer gas supplying mechanism 200 supplying the heat transfer gas is provided not only to the rear surface of the wafer W but also to the rear surface of the focus ring 124, so as to prevent the temperature fluctuation of not only the wafer W but also the focus ring 124. Moreover, by configuring the heat transfer gas supplying mechanism 200 to have different lines by using the first heat transfer gas supply unit 210 supplying the first heat transfer gas to the rear surface of the wafer W and the second heat transfer gas supply unit 220 supplying the second heat transfer gas to the rear surface of the focus ring 124, the thermal conductivity between the susceptor 114 and the focus ring 124 may be controlled independently from the thermal conductivity between the susceptor 114 and the wafer W. As such, the temperature of the focus ring 124 is controlled to improve or freely control the in-plane characteristics of the wafer W.

(Heat Transfer Gas Supplying Mechanism)

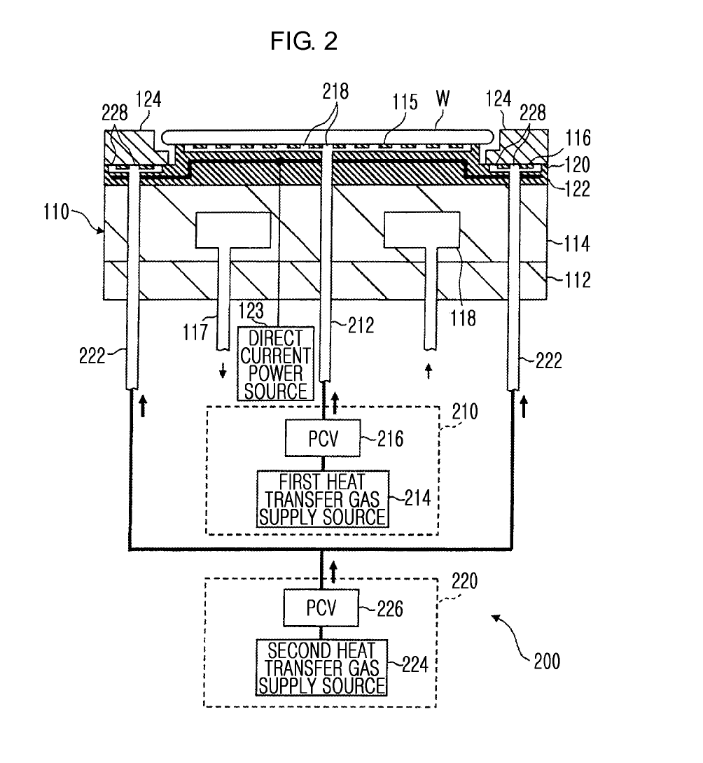

A configuration example of the heat transfer gas supplying mechanism 200 according to the present embodiment will now be described in detail with reference to the drawings. FIG. 2 is a cross-sectional view for describing the configuration example of the heat transfer gas supplying mechanism 200, and the same reference numerals denote the elements having the same functions in FIGS. 1 and 2 and thus, detailed descriptions thereof will be omitted here.

As shown in FIG. 2, the heat transfer gas supplying mechanism 200 includes the first heat transfer gas supply unit 210 and the second heat transfer gas supply unit 220, which are provided in independent and different lines. The first heat transfer gas supply unit 210 supplies the first heat transfer gas at a predetermined pressure between the substrate holding surface 115 of the electrostatic chuck 120 and the rear surface of the wafer W through a first gas passage 212. In detail, the first gas passage 212 penetrates through the insulator 112 and the susceptor 114 and communicates with a plurality of gas holes 218 formed in the substrate holding surface 115. The gas holes 218 herein are formed almost in the entire surface from a center portion to an edge portion of the substrate holding surface 115.

A first heat transfer gas supply source 214 supplying the first heat transfer gas is connected to the first gas passage 212 through a pressure control valve (PCV) 216. The PCV 216 adjusts a flow rate of the first heat transfer gas such that the first heat transfer gas has a predetermined pressure. Also, the number of first gas passages 212 supplying the first heat transfer gas from the first heat transfer gas supply source 214 may be 1 or more.

The second heat transfer gas supply unit 220 supplies the second heat transfer gas at a predetermined pressure between the substrate holding surface 115 of the electrostatic chuck 120 and the rear surface of the focus ring 124 through a second gas passage 222. In detail, the second gas passage 222 penetrates through the insulator 112 and the susceptor 114 and communicates with a plurality of gas holes 228 formed in the focus ring holding surface 116. The gas holes 218 herein are formed almost in the entire surface of the focus ring holding surface 116.

A second heat transfer gas supply source 224 supplying the second heat transfer gas is connected to the second gas passage 222 through a PCV 226. The PCV 226 adjusts a flow rate of the second heat transfer gas such that the second heat transfer gas has a predetermined pressure. Also, the number of second gas passages 222 supplying the second heat transfer gas from the second heat transfer gas supply source 224 may be 1 or more.

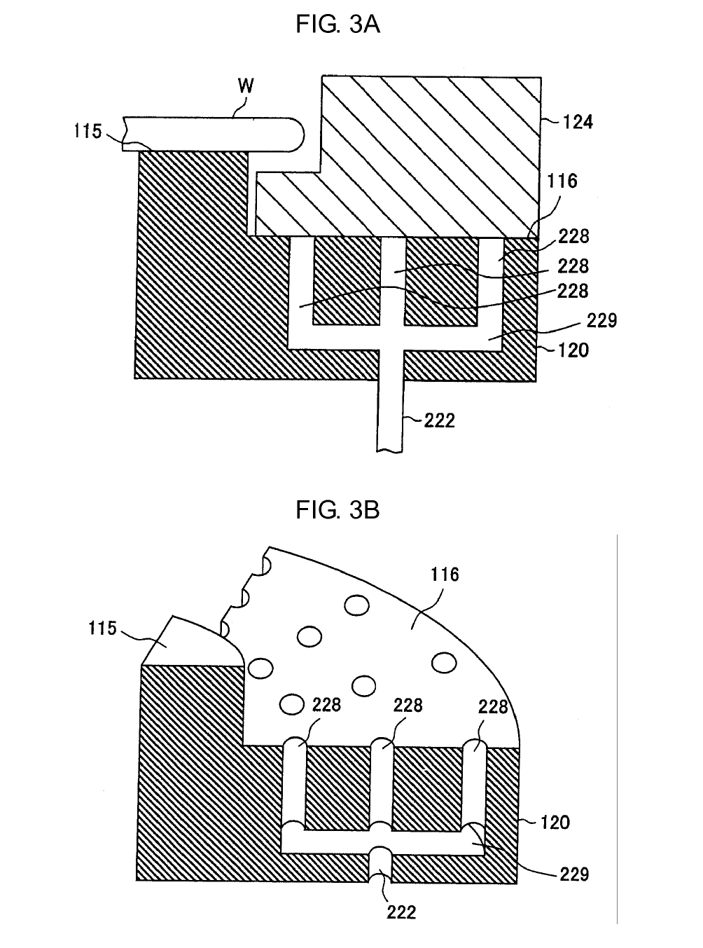

The gas holes 228 provided in the focus ring holding surface 116 may be, for example, configured as shown in FIGS. 3A and 3B. FIG. 3A is a cross-sectional view for describing a configuration example of the gas holes 228, wherein the vicinity of the focus ring 124 of FIG. 2 is partially magnified. FIG. 3B is a perspective view showing a portion excluding the focus ring 124 of FIG. 3A. Also in FIGS. 3A and 3B, the electrode 122 of the electrostatic chuck 120 is not shown.

In the configuration examples of FIGS. 3A and 3B, a first annular diffusion unit 229 formed of an annular space along the circumferential direction of the focus ring 124 is provided inside the electrostatic chuck 120. Also, a lower end of each gas hole 228 is communicated with the upper portion of the first annular diffusion unit 229 while the second gas passage 222 is communicated with the lower portion of the first annular diffusion unit 229. Accordingly, the second heat transfer gas is supplied to the first annular diffusion unit 229 through the second gas passage 222 so as to diffuse the second heat transfer gas throughout along the circumferential direction of the first annular diffusion unit 229 and to eject the second heat transfer gas from each gas hole 228, and thus the second heat transfer gas may be communicated throughout the rear surface of the focus ring 124.

As such, by configuring the first heat transfer gas supply unit 210 supplying the first heat transfer gas to the rear surface of the wafer W and the second heat transfer gas supply unit 220 supplying the second heat transfer gas to the rear surface of the focus ring 124 to have different lines, the pressures or gas species of the heat transfer gases supplied to the rear surface of the wafer W and the rear surface of the focus ring 124 may be changed. Accordingly, the thermal conductivity between the susceptor 114 and the focus ring 124 may be controlled independently from the thermal conductivity between the susceptor 114 and the wafer W. Thus, since the temperature of the focus ring 124 can be controlled, the in-plane process characteristics of the wafer W (for example, the process rate of the edge portion of the wafer W, etc.) may be controlled.

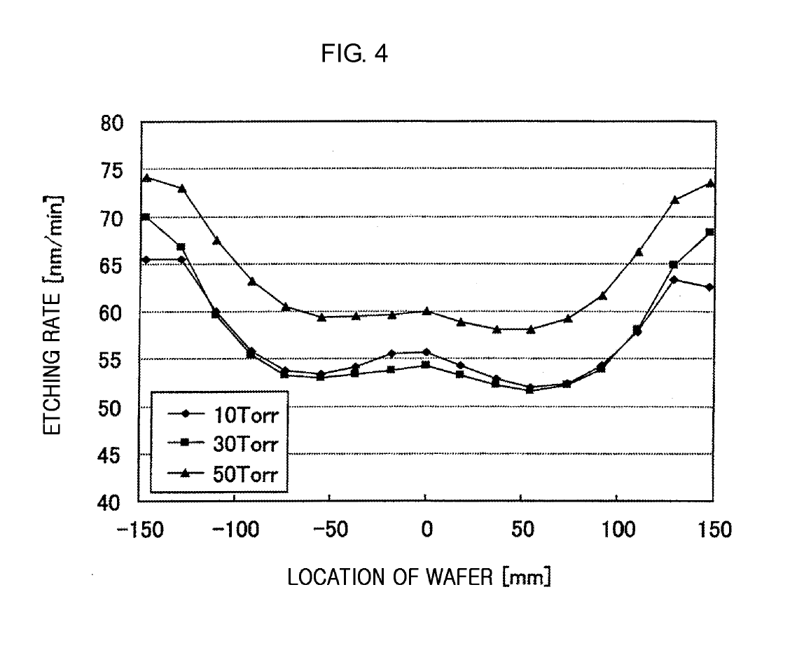

Here, experimental results showing a relationship between the pressure of the second heat transfer gas and the in-plane process characteristics of the wafer W will now be described with reference to the drawings. FIG. 4 is a graph showing the experimental results. In the experiments, a He gas is used for both the first and second heat transfer gases, and the same etching process is performed on a photoresist (PR) film on a wafer having a diameter of 300 mm, wherein the first heat transfer gas is maintained under a fixed pressure (40 Torr herein) while a pressure of the second heat transfer gas is changed to 10 Torr, 30 Torr, and 50 Torr. In FIG. 4, etching rates at a plurality of points from −150 mm to 150 mm, wherein the center of the wafer W is zero, are measured and plotted. Also, other major process conditions are as follows.

[Process Conditions]

Process Gas: C₅F₈ Gas, Ar Gas, O₂ Gas

Pressure in Processing Chamber: 25 mTorr

First Radio frequency (60 MHz): 3300 W

Second Radio frequency (2 MHz): 3800 W

Temperature of Susceptor (Temperature of Lower Electrode): 20° C.

According to the experimental results shown in FIG. 4, the etching rate in the edge portion of the wafer W is higher when the second heat transfer gas is supplied to the rear surface of the focus ring 124 under 30 Torr compared to when supplied under 10 Torr, and thus the etching rate in the center portion of the wafer W is barely changed. This may be because, as the pressure of the second heat transfer gas is higher, the thermal conductivity of the focus ring 124 due to the second heat transfer gas is higher, and thus the temperature of the focus ring 124 may be lower than the temperature of the wafer W. Also, it may be because, as the pressure of the second heat transfer gas is higher, it is easier for the second heat transfer gas to leak around the outer circumference of the wafer W, and thus the etching rate of the edge portion may be affected.

Also, when the pressure of the second heat transfer gas is increased and the second heat transfer gas of 50 Torr is supplied, the etching rate of not only the edge portion but also the center portion of the wafer W is increased. This may be because, as the pressure of the second heat transfer gas is higher, the thermal conductivity of the focus ring 124 due to the second heat transfer gas is higher, and the leak amount of the second heat transfer gas is increased, and thus the etching rate of not only the edge portion but also the center portion is affected.

Accordingly, as the pressure of the second heat transfer gas increases at least in the range from 10 Torr to 30 Torr, only the etching rate of the edge portion of the wafer W may be increased. Also, when the pressure of the second heat transfer gas is increased in the range exceeding at least 50 Torr, the etching rates of both the center portion and edge portion of the wafer W may be increased.

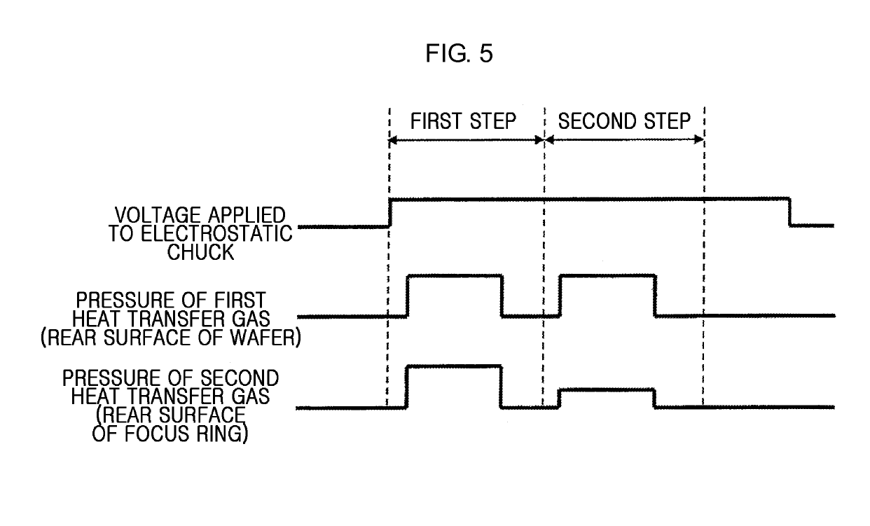

Next, a case when controlling of the in-plane process characteristics by using the pressure of such a heat transfer gas is applied to the process of the wafer W will now be described with reference to the drawings. FIG. 5 is a diagram showing a specific example of a process sequence when the process of the wafer W is performed in a plurality of steps. Herein, pressures of heat transfer gases supplied to a rear surface of a wafer and a rear surface of a focus ring are changed according to steps.

For example, as shown in FIG. 5, a predetermined voltage from the direct current power source 123 is applied to the electrostatic chuck 120 to electrostatically adsorb the wafer W held on the substrate holding surface 115, and then, for example, the first heat transfer gas is supplied under a predetermined pressure while the second heat transfer gas is supplied under the same pressure as the first heat transfer gas, and plasma of the process gas is generated to perform a process of the wafer W.

When the first step is ended, the supplying of the first and second heat transfer gases is stopped, and a second step is performed. In the second step, for example, the first heat transfer gas is supplied under the same pressure as in the first step while the second heat transfer gas is supplied under a pressure lower than the pressure of the first heat transfer gas to generate the plasma of the process gas, thereby performing a process, such as etching, of the wafer W. As such, by individually adjusting the pressures of the first and second heat transfer gases in each step, the optimum in-plane process characteristics of the wafer W may be obtained, and the in-plane process characteristics of the wafer W may be freely controlled.

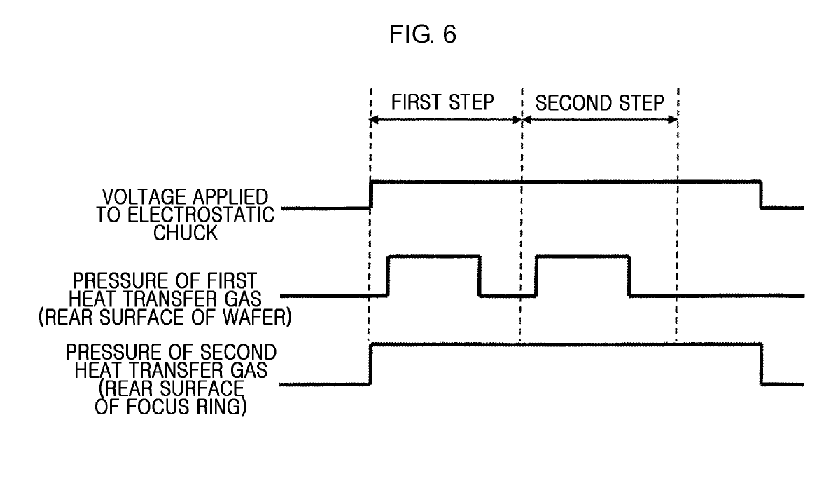

Also in FIG. 5, the first and second heat transfer gases are supplied in each step, but the present invention is not limited thereto. For example, the second heat transfer gas may be continuously supplied in each step. FIG. 6 is a diagram showing another specific example of the process sequence, wherein the first heat transfer gas is supplied according to each step whereas the second heat transfer gas is continuously supplied in each step.

In this case, the second heat transfer gas may be supplied at least while the predetermined voltage is applied to the electrostatic chuck 120 from the direct current power source 123 so that the wafer W is not mis-alignment, cracked, or the like. In FIG. 6, the second heat transfer gas is supplied when the predetermined voltage is applied to the electrostatic chuck 120 from direct current power source 123, and the second heat transfer gas is supplied when the predetermined voltage stops being applied to the electrostatic chuck 120 from the direct current power source 123.

As such, cooling efficiency is increased by continuously cooling the focus ring 124 through a plurality of steps, and thus the etching rate of the edge portion of the wafer W may be even higher.

The controlling of the in-plane process characteristics by changing the pressures of the first and second heat transfer gases has been described above, but the in-plane process characteristics of the wafer W may be controlled by changing the gas species of the first and second heat transfer gases.

For example, a He gas is used as the first heat transfer gas while another inert gas, such as Ar gas or N₂ gas, is used as the second heat transfer gas so as to increase cooling efficiency of the focus ring and control plasma density. Here, since a leak amount can be increased by increasing the pressure of the second heat transfer gas, the plasma density of the edge portion of the wafer W can be controlled. Thus, the process rate in the edge portion may be increased than the process rate in the center portion of the wafer W.

Alternatively, a He gas is used as the first heat transfer gas while a O₂ gas is used as the second heat transfer gas so as to increase the pressure like the inert gas above, thereby increasing the process rate (for example, the etching rate) in the edge portion. Since the O₂ gas can remove a reaction product (deposition) generated by the plasma process (for example, the etching process), the process rate (for example, the etching rate) can be increased.

Alternatively, a He gas is used as the first heat transfer gas while a CF-based (C₅F₈, C₄F₈, C₃F₈, C₄F₈, or the like) gas or CHF-based (CHF₃, CH₂F₂, or the like) gas is used as the second heat transfer gas so as to increase the pressure like the inert gas above, thereby increasing the process rate (for example, the etching rate) of the edge portion of the wafer W. Since the CF-based gas or CHF-based gas can deposit the reaction product (deposition) generated by the plasma process (for example, the etching process), the process rate (for example, the etching rate) of the edge portion of the wafer W can be decreased.

As such, since the heat transfer gas supplying mechanism 200 according to the present embodiment can supply the first heat transfer gas and the second heat transfer gas respectively to the rear surface of the wafer W and the rear surface of the focus ring 124 in different lines, the pressures or gas species of the first and second heat transfer gases can be changed. Accordingly, since the thermal conductivity between the susceptor 114 and the wafer W and the thermal conductivity between the susceptor 114 and the focus ring 124 can be individually controlled by using these heat transfer gases, the temperature of the focus ring 124 is prevented from fluctuating despite the heat input from the plasma, and thus the in-plane uniformity of the wafer W may be improved. Further, there may be an aggressive temperature difference between the temperature of the wafer W and the temperature of the focus ring 124, so as to freely control the in-plane process characteristics of the wafer W.

Also, in the above embodiment, the plurality of gas holes 228 as shown in FIGS. 2, 3, and 4 are formed as communication structure of the second heat transfer gas in the focus ring holding surface 116, but the communication structure is not limited to FIGS. 2, 3, and 4 as long as second heat transfer gas is supplied throughout the rear surface of the focus ring 124.

(Modified Example of Communication Structure of Second Heat Transfer Gas)

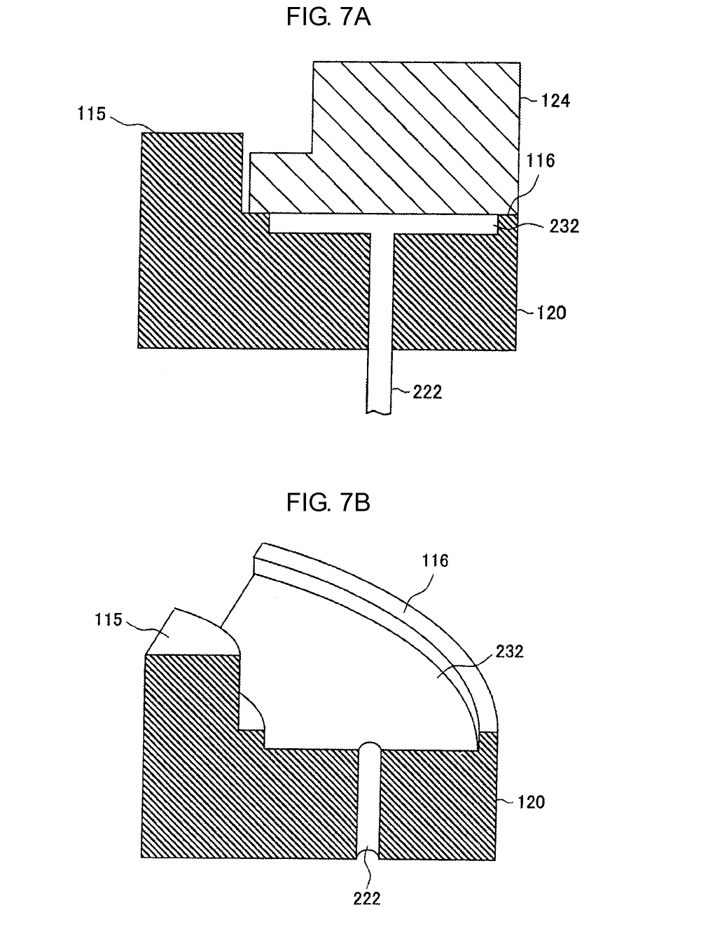

A modified example of the communication structure of the second heat transfer gas in the focus ring holding surface 116 will now be described with reference to the drawings. FIG. 7A is a cross-sectional view for describing the modified example of the communication structure of the second heat transfer gas, wherein the vicinity of the focus ring 124 in the modified example is partially magnified. FIG. 7B is a perspective view showing a portion excluding the focus ring 124 of FIG. 7A. Also in FIGS. 7A and 7B, the electrode 122 of the electrostatic chuck 120 is not shown.

In configuration examples of FIGS. 7A and 7B, a second annular diffusion unit 232 formed of an annular recess portion along the circumferential direction of the focus ring 124 is formed on the surface of the focus ring holding surface 116. The second gas passage 222 is communicated with the second annular diffusion unit 232, and the second heat transfer gas is supplied to the second annular diffusion unit 232 through the second gas passage 222. Accordingly, the second heat transfer gas can be diffused along the circumferential direction throughout the second annular diffusion unit 232 directly below the rear surface of the focus ring 124, and thus can be communicated throughout the rear surface of the focus ring 124.

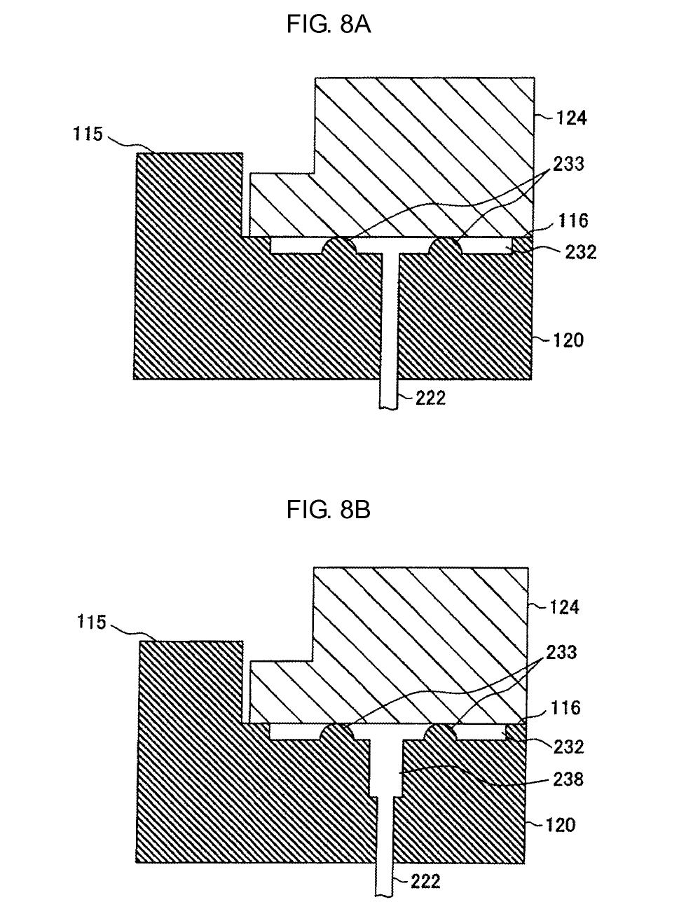

Also as shown in FIG. 8A, a plurality of protruding portions 233 may be provided at the second annular diffusion unit 232 to support the focus ring 124. Accordingly, the plurality of protruding portions 233 may directly contact the rear surface of the focus ring 124 to transfer heat. Thus, a heat transferred portion may be increased by directly contacting the rear surface of the focus ring 124.

Also in this case, a groove portion 238 may be formed at the lower portion of the second annular diffusion unit 232 along the circumferential direction as shown in FIG. 8B, and the second gas passage 222 may communicate with the groove portion 238. Accordingly, even if it is difficult for the second heat transfer gas to be diffused due to a large number of protruding portions 233 of the second annular diffusion unit 232, the second heat transfer gas from the second gas passage 222 is diffused in the circumferential direction through the groove portion 238, and thus easily spreads throughout the second annular diffusion unit 232. Here, a groove width of the groove portion 238 may be larger than a hole diameter of the second gas passage 222 so as to efficiently diffuse the second heat transfer gas input to the groove portion 238 from the second gas passage 222.

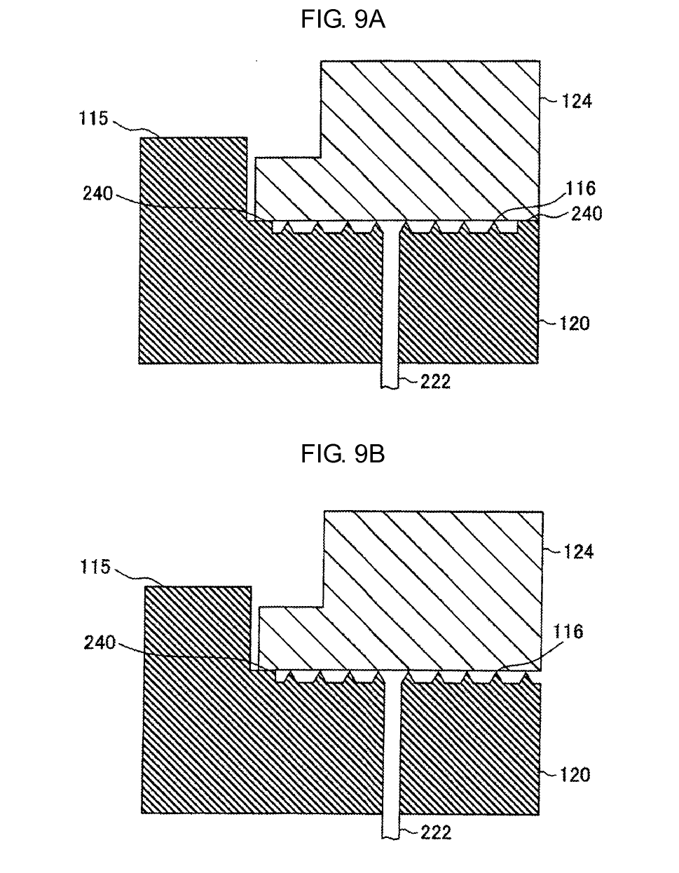

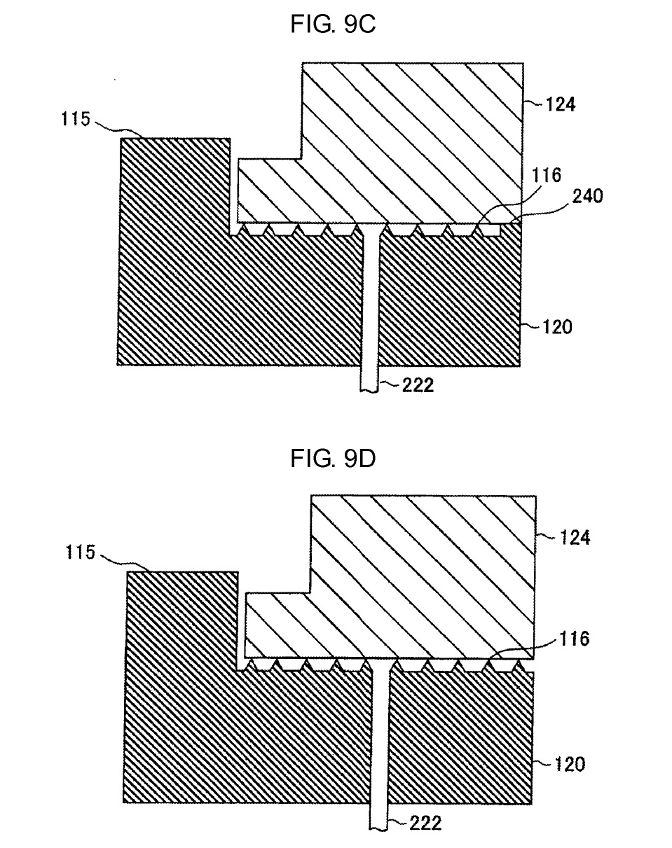

Alternatively, surface roughness of the focus ring holding surface 116 may be increased to diffuse the second heat transfer gas from the second gas passage 222 along the circumferential direction of the focus ring 124 through gaps caused by the rough surface (gaps due to the uneven surface) of the focus ring holding surface 116. In detail, for example, a portion having high surface roughness for the second heat transfer gas to communicate the focus ring holding surface 116 is formed along the circumferential direction of the focus ring 124, as shown in FIG. 9A. Also, the second gas passage 222 is communicated with the portion having the high surface roughness.

Here, as shown in FIG. 9A, a sealing portion 240 sealing the second heat transfer gas may be provided at both the inner circumference and outer circumference of the focus ring holding surface 116. Accordingly, it is difficult for the second heat transfer gas to leak from the inner and outer circumferences of the focus ring holding surface 116 compared to a case when there is no sealing portion 240. Thus, the second heat transfer gas increases a heat transfer effect of the focus ring 124, and thus the process characteristics of the edge portion of the wafer W can be controlled.

Alternatively, the sealing portion 240 may not be provided at one or both of the inner and outer circumferences of the focus ring holding surface 116, so that the second heat transfer gas is actively leaked from one or both of the inner and outer circumferences. Accordingly, since the second heat transfer gas is leaked in the vicinity of the edge portion of the wafer W, in addition to the heat transfer effect due to the second heat transfer gas, the process characteristics of the edge portion of the wafer W can be controlled even by changing a ratio of gas components near the edge portion.

In FIG. 9B, the sealing portion 240 is provided only at the inner circumference of the focus ring holding surface 116, so that the second heat transfer gas is easily leaked from the outer circumference. On the other hand, in FIG. 9C, the sealing portion 240 is provided only at the outer circumference of the focus ring holding surface 116, so that the second heat transfer gas is easily leaked from the inner circumference. In FIG. 9D, the sealing portion 240 is provided at neither the inner or outer circumference of the focus ring holding surface 116, so that the second heat transfer gas is easily leaked from both inner and outer circumferences.

Also, the groove portion 238 shown in FIG. 8B may be formed at the focus ring holding surface 116 shown in FIGS. 9A through 9D so that the second gas passage 222 may communicate with the groove portion 238. Accordingly, the second heat transfer gas from the second gas passage 222 is diffused in the circumferential direction through the groove portion 238 regardless of a degree of surface roughness of the focus ring holding surface 116, and thus the second heat transfer gas is easily spread throughout the focus ring holding surface 116. In this case, the groove width of the groove portion 238 may be larger than the hole diameter of the second gas passage 222 like FIG. 8B, so that the second heat transfer gas input to the groove portion 238 from the second gas passage 222 is efficiently spread.

Also, the sealing portion 240 shown in FIGS. 9A through 9C may be applied to a surface structure of the focus ring holding surface 116 provided with the protruding portion 233 of FIG. 8A. Alternatively, the sealing portion 240 may not be provided on neither inner or outer circumference in the surface structure of the focus ring holding surface 116 shown in FIG. 8A.

(Surface Process of Electrostatic Chuck)

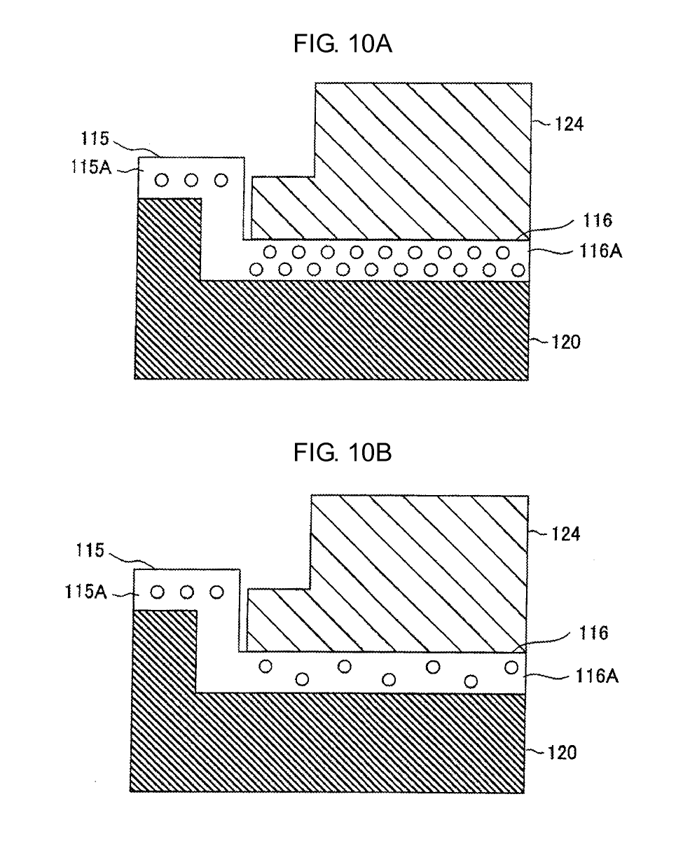

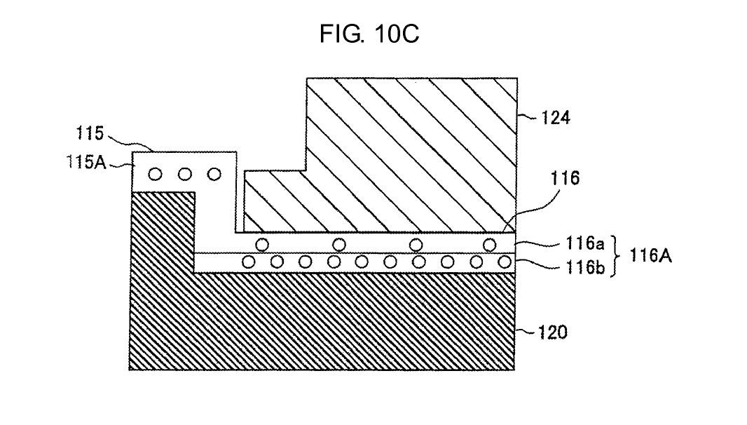

Next, a surface process of the electrostatic chuck 120 will now be described. A sprayed film formed of, for example, Al₂O₃ or Y₂O₃, is formed on a surface of the electrostatic chuck 120 via spraying (for example, refer to a sprayed film 115A or 116A shown in FIG. 10A that will be described later). Here, porosity of the sprayed film 116A of the focus ring holding surface 116 is changed with respect to porosity of the sprayed film 115A of the substrate holding surface 115 to change the thermal conductivity from the focus ring holding surface 116 to the focus ring 124, thereby controlling the temperature of the focus ring 124.

Here, when Q denotes a heat amount from plasma, S denotes an area of the focus ring holding surface 116, L denotes a thickness of a sprayed film, and dT denotes a temperature difference between a top surface (surface of the focus ring holding surface 116) and a bottom surface of the sprayed film 116A, thermal conductivity k is represented by Equation 1 below. Thus, the temperature difference dT between the top and bottom surfaces of the sprayed film 116A may be represented by Equation 2 below from Equation 1.

k[W/cmK]=(Q·S)/(dT·L) (1)

dT=(Q·S)/(k·L) (2)

According to Equation 2 above, as the thermal conductivity k is decreased by increasing the porosity of the sprayed film 116A, the temperature of the surface (top surface of the sprayed film 116A) of the focus ring holding surface 116 is increased, and thus the temperature of the focus ring 124 may be controlled in a relatively high temperature range. On the other hand, as the thermal conductivity k is increased by decreasing the porosity of the sprayed film 116A, the temperature of the surface (top surface of the sprayed film 116A) of the focus ring holding surface 116 is decreased, and thus the temperature of the focus ring 124 may be controlled in a relatively low temperature range.

Here, a specific example of changing the porosity of the sprayed film 116A of the focus ring holding surface 116 will now be described with reference to the drawings. FIG. 10A is a partial cross-sectional view of a case when the porosity of the sprayed film 116A of the focus ring holding surface 116 is larger than the porosity of the sprayed film 115A of the substrate holding surface 115, and FIG. 10B is a partial cross-sectional view of a case when the porosity of the sprayed film 116A of the focus ring holding surface 116 is smaller than the porosity of the sprayed film 115A of the substrate holding surface 115. FIGS. 10A and 10B conceptually show a difference of porosities of the sprayed films 115A and 116A. Also, in FIGS. 10A and 10B, the heat transfer gas supplying mechanism 200, and the electrode 122 of the electrostatic chuck 120 are not shown.

As shown in FIG. 10A, when the porosity of the sprayed film 116A of the focus ring holding surface 116 is higher than the porosity of the sprayed film 115A of the substrate holding surface 115, the thermal conductivity of the focus ring holding surface 116 is decreased. For example, when the porosity of the sprayed film 115A of the substrate holding surface 115 is 5%, the porosity of the sprayed film 116A of the focus ring holding surface 116 is 8%. Accordingly, the cooling effect by the second heat transfer gas with respect to the temperature increase by the plasma heat input is lower in the focus ring 124 than in the wafer W, and thus the temperature of the focus ring 124 can be controlled in a relatively high temperature range (for example, 100° C. or above).

On the other hand, as shown in FIG. 10B, when the porosity of the sprayed film 116A of the focus ring holding surface 116 is smaller than that of the substrate holding surface 115, the thermal conductivity of the focus ring holding surface 116 is increased. For example, when the porosity of the sprayed film 115A of the substrate holding surface 115 is 5% as above, the porosity of the sprayed film 116A of the focus ring holding surface 116 is 2%. Accordingly, the cooling effect by the second heat transfer gas with respect to the temperature increase by the plasma heat input is higher in the focus ring 124 than that in the wafer W, and thus the temperature of the focus ring 124 can be controlled in a relatively low temperature range (for example, 0° C. to 20° C.).

Also, the heat transfer from the focus ring holding surface 116 to the focus ring 124 includes heat transfer from a portion contacting the heat transfer gas (for example, a He gas), as well as heat transfer from a portion contacting the sprayed film 116A. As the porosity of the sprayed film 116A is higher, the contribution according to the heat transfer from the portion contacting the heat transfer gas is relatively higher. On the other hand, as the porosity of the sprayed film 116A is lower, the contribution according to the heat transfer from the portion contacting the sprayed film 116A is relatively lower. Accordingly, the porosity of the sprayed film 116A is changed as occasion demands, so as to change the contribution of the heat transfer from the sprayed film 116A and the heat transfer from the heat transfer gas. Accordingly, the temperature control efficiency (for example, cooling efficiency) of the focus ring 124 may be increased.

Also, in FIGS. 10A and 10B, the sprayed film 116A of the focus ring holding surface 116 is one layer, but the present invention is not limited thereto, and the sprayed film 116A of the focus ring holding surface 116 may be a plurality of layers, and the porosity of each layer may be changed. For example, FIG. 10C is a partial cross-sectional view of a case where the sprayed film 116A of the focus ring holding surface 116 is two layers. FIG. 10C conceptually shows a difference between the porosities of the layers.

In detail, in FIG. 10C, the sprayed film 116A of the focus ring holding surface 116 includes two layers of an upper sprayed film 116a and a lower sprayed film 116b. The porosities of the upper and lower sprayed films 116a and 116b may be changed to change the entire porosity of the sprayed film 116A. Here, the upper and lower sprayed films 116a and 116 may be formed of the same material or different species of materials.

When different species of materials are used, for example, the lower sprayed film 116b may be a partially stabilized zirconia (PSZ) sprayed film, and the upper sprayed film 116a may be formed by forming a Al₂O₃ or Y₂O₃ sprayed film thereon. Accordingly, the entire porosity of the sprayed film 116A may be changed. For example, when the porosity of a PSZ layer constituting the lower sprayed film 116b is increased, the entire porosity of the sprayed film 116A may be increased just by forming the upper sprayed film 116a with Al₂O₃ or Y₂O₃. Here, a process for changing the porosity of the upper sprayed film 116a formed of Al₂O₃ or Y₂O₃ may be skipped, and the entire porosity of the sprayed film 116A may be relatively easily increased.

(Another Configuration Example of Heat Transfer Gas Supplying Mechanism)

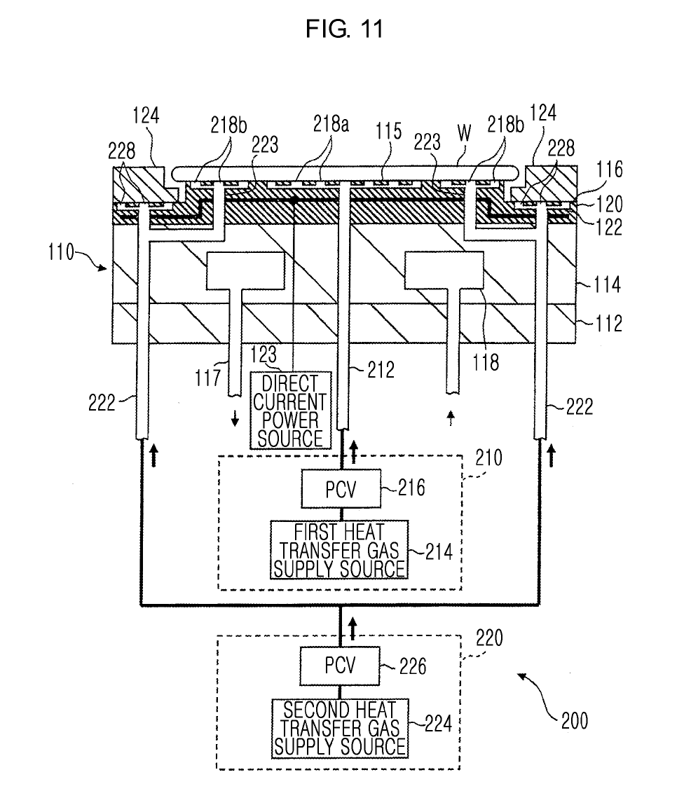

Next, another configuration example of the heat transfer gas supplying mechanism 200 will now be described with reference to the drawings. FIG. 11 is a cross-sectional view showing the other configuration example of the heat transfer gas supplying mechanism 200 according to the present embodiment. In the configuration example of the heat transfer gas supplying mechanism 200 shown in FIG. 2, the second heat transfer gas is supplied to the rear surface of the focus ring 124, but, in the present embodiment, the second heat transfer gas is supplied not only to the rear surface of the focus ring 124 but also to the rear surface of the edge portion of the wafer W.

In detail, for example, the second gas passage 222 may be branched to a branch passage 223 provided toward the rear surface of the edge portion of the wafer W as shown in FIG. 11. In this case, the gas holes 218 of the substrate holding surface 115 are divided into center portion region gas holes 218a and edge portion region gas holes 218b around the center portion region gas holes 218a, wherein the center portion region gas holes 218a are communicated with the first gas passage 212 and the edge portion region gas holes 218b are communicated with the branch passage 223 branched from the second gas passage 222. Accordingly, the first heat transfer gas is supplied to the center portion region gas holes 218a while the second heat transfer gas is supplied to the edge portion region gas holes 218b.

According to the configuration shown in FIG. 11, not only the temperature of the focus ring 124 but also the temperature of the edge portion region of the wafer W is controlled independently from the temperature of the center portion region by using the second heat transfer gas, and thus the process characteristics of the edge portion region of the wafer W cab be directly controlled.

The present invention is applicable to a substrate processing apparatus and a substrate processing method, which perform a plasma process on a substrate, such as a semiconductor wafer.

According to the present invention, the thermal conductivity between the rear surface of the substrate and the temperature controlled susceptor and the thermal conductivity between the rear surface of the focus ring and the temperature controlled susceptor can be individually changed by electrostatically adsorbing both of the substrate and the focus ring and supplying the heat transfer gas individually not only to the rear surface of the substrate but also to the rear surface of the focus ring, thereby controlling the temperature of the focus ring independently from the temperature of the substrate. Accordingly, the in-plane process characteristics of the substrate may be improved or freely controlled.

While this invention has been particularly shown and described with reference to exemplary embodiments thereof, this invention is not limited thereto. It will be understood by those skilled in the art that various changes in form and details may be made therein without departing from the spirit and scope of the invention as defined by the appended claims.

For example, the above embodiment exemplifies a substrate processing apparatus that generates plasma by overlappingly applying two types of radio frequency power only to a lower electrode, but the present invention is not limited thereto, and a substrate processing apparatus may apply one type of radio frequency power only to a lower electrode or two types of radio frequency power to each of lower and upper electrodes.

What is claimed is:

1. A substrate processing apparatus which performs a plasma process on a substrate, with the substrate being disposed in a processing chamber and a focus ring being disposed to surround the substrate, the substrate processing apparatus comprising:
a holding stage which comprises a susceptor having a substrate holding surface on which the substrate is held and a focus ring holding surface on which the focus ring is held;
a susceptor temperature control mechanism which adjusts a temperature of the susceptor;
a substrate holding unit which electrostatically adsorbs a rear surface of the substrate to the substrate holding surface and electrostatically adsorbs a rear surface of the focus ring to the focus ring holding surface; and
a heat transfer gas supplying mechanism which independently provides a first heat transfer gas supply unit supplying a first heat transfer gas to the rear surface of the substrate and a second heat transfer gas supply unit supplying a second heat transfer gas to the rear surface of the focus ring.

2. The substrate processing apparatus of claim 1, wherein the heat transfer gas supplying mechanism independently provides a first gas passage connected to the first heat transfer gas supply unit and a second gas passage connected to the second heat transfer gas supply unit, wherein the first gas passage communicates with a plurality of gas holes formed in the substrate holding surface and the second gas passage communicates with a plurality of gas holes formed in the focus ring holding surface.

3. The substrate processing apparatus of claim 2, wherein a first annular diffusion unit which is formed of an annular space along a circumferential direction of the focus ring is provided below the focus ring holding surface, wherein the plurality of gas holes of the focus ring holding surface communicates with the top of the first annular diffusion unit and the second gas passage communicates with the bottom of the first annular diffusion unit.

4. The substrate processing apparatus of claim 1, wherein the heat transfer gas supplying mechanism independently provides a first gas passage connected to the first heat transfer gas supply unit and a second gas passage connected to the second heat transfer gas supply unit, wherein the first gas passage communicates with a plurality of gas holes formed in the substrate holding surface, and the second gas passage communicates with a second annular diffusion unit formed of an annular recess portion formed along a circumferential direction of the focus ring on the focus ring holding surface.

5. The substrate processing apparatus of claim 4, wherein a plurality of protruding portions supporting the rear surface of the focus ring are formed in the second annular diffusion unit.

6. The substrate processing apparatus of claim 5, wherein a groove portion is formed along a circumferential direction of the second annular diffusion unit below the second annular diffusion unit, wherein the second gas passage communicates with the groove portion.

7. The substrate processing apparatus of claim 1, wherein the heat transfer gas supplying mechanism independently provides a first gas passage connected to the first heat transfer gas supply unit and a second gas passage connected to the second heat transfer gas supply unit, wherein the first gas passage communicates with a plurality of gas holes formed in the substrate holding surface, and the second gas passage communicates with a portion formed along a circumferential direction of the focus ring, wherein surface roughness of the portion is rough enough for the second heat transfer gas to communicate to the focus ring holding surface.

8. The substrate processing apparatus of claim 7, wherein a sealing portion which seals the second heat transfer gas is provided on both inner and outer circumferences of the focus ring holding surface.

9. The substrate processing apparatus of claim 8, wherein the sealing portion on one or both inner and outer circumferences of the focus ring holding surface is removed.

10. The substrate processing apparatus of claim 1, wherein a sprayed film is formed on a surface of the focus ring holding surface and a surface of the substrate holding surface, and
in-plane process characteristics of the substrate are controlled by changing porosity of the sprayed film of the focus ring holding surface with respect to porosity of the sprayed film of the substrate holding surface.

11. The substrate processing apparatus of claim 10, wherein the porosity of the sprayed film of the focus ring holding surface is determined according to a control temperature range of the susceptor.

12. The substrate processing apparatus of claim 1, wherein a plurality of gas holes in the substrate holding surface are disposed in a center portion region of the substrate holding surface and an edge portion region of the substrate holding surface, with the edge portion region being around the center portion region,
wherein the first gas passage communicates with the plurality of gas holes in the center portion region of the substrate holding surface, and the second gas passage is branched into two passages, wherein one passage communicates with the plurality of gas holes formed in the focus ring holding surface and the other passage communicates with the plurality of gas holes in the edge portion region of the substrate holding surface.

13. A substrate processing method of processing a substrate processing apparatus which performs a plasma process on a substrate, with the substrate being disposed in a processing chamber and a focus ring being disposed to surround the substrate, the substrate processing apparatus comprising:
a holding stage which comprises a susceptor having a substrate holding surface on which the substrate is held and a focus ring holding surface on which the focus ring is held;
a susceptor temperature control mechanism which adjusts a temperature of the susceptor;
a substrate holding unit which electrostatically adsorbs a rear surface of the substrate to the substrate holding surface and electrostatically adsorbs a rear surface of the focus ring to the focus ring holding surface; and
a heat transfer gas supplying mechanism which independently provides a first heat transfer gas supply unit supplying a first heat transfer gas to a rear surface of the substrate under a predetermined pressure and a second heat transfer gas supply unit supplying a second heat transfer gas to a rear surface of the focus ring under a predetermined pressure,
the substrate processing method comprising controlling in-plane process characteristics of the substrate by changing a supply pressure of the second heat transfer gas with respect to a supply pressure of the first heat transfer gas.

14. A substrate processing method of processing a substrate processing apparatus which performs a plasma process on a substrate, with the substrate being disposed in a processing chamber and a focus ring being disposed to surround the substrate, the substrate processing apparatus comprising:
a holding stage which comprises a susceptor having a substrate holding surface on which the substrate is held and a focus ring holding surface on which the focus ring is held;
a susceptor temperature control mechanism which adjusts a temperature of the susceptor;
a substrate holding unit which electrostatically adsorbs a rear surface of the substrate to the substrate holding surface and electrostatically adsorbs a rear surface of the focus ring to the focus ring holding surface; and
a heat transfer gas supplying mechanism which independently provides a first heat transfer gas supply unit supplying a first heat transfer gas to a rear surface of the substrate under a predetermined pressure and a second heat transfer gas supply unit supplying a second heat transfer gas to a rear surface of the focus ring under a predetermined pressure,
the substrate processing method comprising controlling in-plane process characteristics of the substrate by changing gas species of the first and second heat transfer gases.
